(19) United States
(12) Patent Application Publication
(10) Pub. No.: US 2025/0035677 A1
(43) Pub. Date: Jan. 30, 2025

(54) ELECTROCHEMICAL DEVICE MONITORING

(71) Applicant: UNIVERSITY OF NEWCASTLE UPON TYNE, Newcastle (GB)

(72) Inventors: Mohamed MAMLOUK, Newcastle (GB); Keith SCOTT, Newcastle (GB)

(21) Appl. No.: 18/716,261

(22) PCT Filed: Dec. 7, 2022
(86) PCT No.: PCT/GB2022/053124

§ 371 Date: Jun. 4, 2024

(30) Foreign Application Priority Data
Dec. 7, 2021 (GB) 2117664.9

(51) Int. Cl. G01R 15/24; G01R 31/396; G01R 33/032

(52) U.S. Cl. CPC G01R 15/245; G01R 31/396; G01R 33/032

(57) ABSTRACT

A system is disclosed, the system comprising: an electrochemical device generating a magnetic field; and a sensing device comprising: a magneto-optical medium; an electromagnetic radiation source configured to emit polarized electromagnetic radiation through the magneto-optical medium; and a sensor configured to receive polarized electromagnetic radiation which has passed through the magneto-optical medium. The sensing device is arranged relative to the electrochemical device such that the magnetic field of the electrochemical device passes through the magneto-optical medium.

### TECHNICAL FIELD

The present invention relates to electrochemical device monitoring and particularly, but not exclusively, to a system suitable for monitoring characteristics of an electrochemical device using the Faraday effect. Aspects of the invention relate to a system, to a method of monitoring, and to various sensor configurations.

### BACKGROUND

Current distribution measurements in electrochemical devices are crucial for their operation and durability. These could arise from manufacturing faults (e.g. inhomogenous mixing or deposition of active materials), or concentration gradients (e.g. flooding or oxygen starvation in fuel cell) at high current densities. Additionally, some electrochemical devices used in various industries are moving towards higher power outputs and thus require higher current densities.

Currently, power management systems monitor electrochemical devices, such as fuel cells, batteries or electrolysers by measuring individual cell voltage across 100s of cells. The measured current (or reaction rates) is not homogeneously distributed through the cells, particularly at high rates where small areas of an electrode could operate at significantly higher current density than the rest of the electrode. Standard techniques cannot detect these variations. Since cells are assembled in stacks and modules, a failure of one of the cells could impact and compromise adjacent cells and possibly the whole battery module or stack of cells. Importantly, if one of the cell started go into thermal runaway this could cause catastrophic failure of the whole system due to propagation. Despite strict quality control of and examination of each of electrochemical cells (e.g. battery) in the assembly, catastrophic failure and battery fires still occur in electric vehicles initiated by a single faulty battery.

It is possible to measure current distribution within cells in an array of electrodes. This requires breaking down one cell to an array of small cells and logging temperature variation in different locations across the array of electrodes. Constructing a cell electrode out of a smaller array of electrodes has limited resolution because of the size of a unit cell. In addition, this method is complex and costly. Further, monitoring current distribution in this way increases the chance of leaks and resistance within the electrode array, which can decrease the effectiveness of the electrode. Using temperature variation also has practical limitation as batteries and cells are usually cooled to have uniform temperature.

WO2021/019405A1 describes a sensing apparatus which can chemically sample a battery, through extraction of battery liquid. The extracted fluid is then analysed using known spectroscopy methods to determine battery health. This is discussed further in Grey, C. and Baumberg, J. In-operando battery chemistry monitoring. University of Cambridge Enterprise.[online]Available at: https://www.enterprise.cam.ac.uk/opportunities/commercial-opportunity-in-operando-battery-chemistry-monitoring/[Accessed 27 Oct. 2021]. The method thus requires extraction of fluid in order to provide monitoring of battery health. It would be useful to provide a non-invasive method of determining the health of any electrochemical device, including non-fluidic batteries. Such non invasive method can be used in operating system as real time monitoring of battery health but can also be used after battery manufacturing for quality control verification prior to stack/modules assembly.

It is an aim of certain examples of the present invention to solve, mitigate or obviate, at least partly, at least one of the problems or disadvantages associated with the prior art. Certain examples aim to provide at least one of the advantages described below.

### BRIEF SUMMARY OF THE INVENTION

Aspects of the invention provide a system, a method, and sensors as claimed in the appended claims.

According to an aspect of the invention, there is provided a system comprising: an electrochemical device generating a magnetic field; and a sensing device comprising: a magneto-optical medium; an electromagnetic radiation source configured to emit polarized electromagnetic radiation through the magneto-optical medium; and a sensor configured to receive polarized electromagnetic radiation which has passed through the magneto-optical medium; the sensing device is arranged relative to the electrochemical device such that the magnetic field of the electrochemical device passes through the magneto-optical medium.

The system may include the magneto-optical medium positioned such that the magnetic field of the electrochemical device interacts with the magneto-optical medium to rotate a polarization plane of the polarized electromagnetic radiation based on a characteristic of the electrochemical device.

The system may include the electromagnetic radiation source arranged relative to the electrochemical device such that the emitted polarized electromagnetic radiation is parallel to the generated magnetic field of the electrochemical device.

The system may include the magneto-optical medium integral with the electromagnetic radiation source.

The system may include the magneto-optical medium as a layer coupled to the electrochemical device.

The magneto-optical medium may include thin film magneto-optical crystals.

The sensing device may further comprise a protective layer of an insulating polymer or glass film for protecting the thin film magneto-optical crystals. The magneto-optical crystals may be embedded with a polymer or glass fibre for protecting the thin film magneto-optical crystals.

The magneto-optical crystals may have a high Verdet constant or low optical adsorption.

The magneto-optical crystals may comprise at least one of barium hexaferrites, terbium gallium garnet, bismuth doped rare earth iron garnet, Na₂Ce(MoO₄)₂ or CeAlO₃.

The electrochemical device generating a magnetic field may be a battery comprising a plurality of cells; the system may comprise a plurality of electromagnetic radiation sources, each associated with one of the plurality of cells. The system may further comprise a plurality of magneto-optical mediums, each associated with one of the plurality of cells.

The system may be configured to operate the plurality of electromagnetic radiation sources in series.

The sensor may be configured to receive polarized electromagnetic radiation which has passed through one of the plurality of magneto-optical mediums from each of the electromagnetic radiation sources.

The system may further comprise a plurality of sensors associated with the plurality of electromagnetic radiation sources.

The system may comprise a control module configured to: determine a first polarization plane of the emitted electromagnetic radiation, or store a predetermined polarization plane of the emitted electromagnetic radiation; determine a second polarization plane of the electromagnetic radiation which has passed through the magneto-optical medium; determine an angle of rotation between the first and second polarization planes; determine a magnetic field strength of the electrochemical device based on the determined angle of rotation; and determine the current distribution of the electrochemical device based on the determined magnetic field.

According to an aspect of the invention, there is provided a method of sensing comprising: providing the system described above; emitting, from the electromagnetic radiation source, a polarized electromagnetic radiation through the magneto-optical medium; receiving, with the sensor, the polarized electromagnetic radiation which has passed through the magneto-optical medium.

The method may further comprise determining an angle of rotation of a polarization plane of the reflected electromagnetic radiation.

The method may further comprise determining the magnetic field strength an electrochemical device based on the determined angle of rotation; and determining the current distribution of the electrochemical device based on the determined magnetic field.

The method may further comprise repeating the determination of the current distribution of the electrochemical device periodically or for a plurality of positions upon the electrochemical device; and determining a temporal or spatial variation in current distribution information of the electrochemical device.

Emitting the polarized electromagnetic radiation to a magneto-optical medium may comprise emitting the electromagnetic radiation from a plurality of fibre optic cables.

The electromagnetic radiation may be emitted from the plurality of fibre optic cables independently over the time period such that the electromagnetic radiation is incident on the magneto-optical medium in a pattern or series.

The electromagnetic radiation may be emitted from the plurality of fibre optic cables simultaneously and the plurality of fibre optic cables may be configured to emit a different wavelength of electromagnetic radiation to an adjacent fibre optic cable.

The system may comprise a control module configured to receive the variation in current distribution information; and the control module may be configured to change a parameter of the electrochemical device based on the variation in current distribution information. The control module may be configured to trigger an alarm based on the variation in current distribution information.

According to an aspect of the invention, there is provided a sensing device comprising: a magneto-optical medium; an electromagnetic radiation source configured to emit polarized electromagnetic radiation through the magneto-optical medium; and a sensor configured to receive polarized electromagnetic radiation reflected from the electromagnetic radiation source through the magneto-optical medium, the electromagnetic radiation source comprises a first plurality of fibre optic cables, or the sensor comprises a second plurality of fibre optic cables.

The sensing device may further comprise at least one of a reflective layer or a protective medium.

The first plurality of fibre optic cables and the second plurality of fibre optic cables may be arranged in a mesh or woven array.

At least one of the first or second plurality of fibre optic cables may be configured to be embedded inside the electrochemical device.

The first plurality of fibre optic cables may be configured to emit electromagnetic radiation independently over a period of time such that the electromagnetic radiation is incident on the magneto-optical medium in a pattern or series.

The electromagnetic radiation may be emitted from the first plurality of fibre optic cables simultaneously and the first plurality of fibre optic cables may be configured to emit a different wavelength of electromagnetic radiation to an adjacent fibre optic cable.

According to an aspect of the invention, there is provided a sensing device comprising: an electromagnetic radiation source comprising a first plurality of fibre optic cables for emitting polarized electromagnetic radiation; and a sensor configured to receive polarized electromagnetic radiation, the sensor comprises the magneto-optical medium such that the polarized electromagnetic radiation from the electromagnetic radiation source passes through magneto-optical medium.

The sensor may comprise a second plurality of fibre optic cables. The second plurality of fibre optic cables may contain the magneto-optical medium.

At least one fibre optic cable may comprise a reflective layer.

The first plurality of fibre optic cables may be configured to emit electromagnetic radiation independently over a period of time.

The electromagnetic radiation may be emitted from the first plurality of fibre optic cables simultaneously and the first plurality of fibre optic cables may be configured to emit a different wavelength of electromagnetic radiation to an adjacent fibre optic cable.

According to an aspect of the invention, there is provided a use of a sensing device for determining current variation in an electrochemical device.

### BRIEF DESCRIPTION OF THE DRAWINGS

Examples of the invention are further described hereinafter with reference to the accompanying drawings, in which:

FIG. 1 is a schematic view of an example system for monitoring an electrochemical device;

FIG. 2 is a schematic view of another example system for monitoring an electrochemical device;

FIG. 3 is a schematic view of an example of a fibre optic array;

FIG. 4 is a schematic view of example system for monitoring an electrochemical device with a fibre optic;

FIG. 5 is a schematic view of another example system for monitoring an electrochemical device with a fibre optic;

FIG. 6 is a schematic view of a yet further example system for monitoring an electrochemical device with a fibre optic;

FIG. 7 illustrates an example method of monitoring an electrochemical device;

FIG. 8 illustrates the method of FIG. 7, further including determining an angle of rotation;

FIG. 9 illustrates the method of FIG. 8, further including determining the current distribution of the electrochemical device;

FIGS. 10A and 10B illustrate example results of heterogeneity of current in an Li Pouch Cell 2000 mAh and an Li Pouch Cell 4000 mAh, respectively;

FIG. 11A illustrates an example of a magnetic field maps determined using the methodology of FIG. 9;

FIG. 11B illustrates magnetic field mapping changes with time during first discharge cycle of small section of 20.5 mm×15.5 mm of 4000 mAh Li-ion battery during discharge rates 2 C (8 A) after 10, 300, 600 and 800s or equivalent state of charge of 99.7, 91.7, 83.3 and 77.8%;

FIG. 11C illustrates magnetic field mapping changes with time during fortieth discharge cycle of small section of 20.5 mm×15.5 mm of 4000 mAh Li-ion battery during discharge rates 2 C (8 A) after 10, 300, 600 and 800s;

FIG. 11D illustrates comparison of magnetic field map of 1st and 40th discharge cycles of small section of 20.5 mm×15.5 mm of 4000 mAh Li-ion battery during discharge rates at 8 A after 60, 120, 600 and 180s; and

FIG. 12 illustrates a comparison of 1st and 40th discharge cycles of the 4000 mAh Li-ion battery at 8 A.

Like numerals refer to like features.

### DETAILED DESCRIPTION

It will be appreciated that examples of the present invention can be realized in the form of hardware, software or a combination of hardware and software. Any such software may be stored in the form of volatile or non-volatile storage, for example a storage device like a ROM, whether erasable or rewritable or not, or in the form of memory, for example RAM, memory chips, device or integrated circuits or on an optically or magnetically readable medium, for example a CD, DVD, magnetic disk or magnetic tape or the like. It will be appreciated that the storage devices and storage media are examples of machine-readable storage that are suitable for storing a program or programs comprising instructions that, when executed, implement examples of the present invention.

Accordingly, examples provide a program comprising code for implementing apparatus or a method as claimed in any one of the claims of this specification and a machine-readable storage storing such a program. Still further, such programs may be conveyed electronically via any medium, for example a communication signal carried over a wired or wireless connection and examples suitably encompass the same.

Throughout the specification reference is made to an electrochemical device. An electrochemical device is intended to encompass any device which can generate electricity from a chemical reaction or use electrical energy to cause chemical reactions. This includes but is not limited to, batteries and cells thereof, electrolysers, sensors, fuel cells, water electrolysers, etc.

The present invention utilises the Faraday effect (or Faraday rotation) in order to map the current distribution of an electrochemical device. An electrochemical device has a magnetic field in a plane perpendicular to the direction of the electric current. When polarized electromagnetic radiation is passed through a material, the plane of polarization is rotated by an angle proportional to the magnetic field intensity. The relation between the angle of rotation of the polarization and the magnetic field in a material is given by Bequerel's formula:

$$β = VBd \qquad Equation . 1$$

β is the angle of rotation (in radians), B is the magnetic flux density in the direction of propagation (in Teslas), d is the length of the path (in meters) in which the electromagnetic radiation and magnetic field interact, and V is the Verdet constant for the material. This empirical proportionality constant (in units of radians per tesla per meter) varies with wavelength and temperature and is tabulated for various materials. A positive Verdet constant corresponds to L-rotation (anticlockwise) when the direction of propagation is parallel to the magnetic field and to R-rotation (clockwise) when the direction of propagation is anti-parallel. Thus, if a ray of electromagnetic radiation is passed through a material and reflected back through it, the rotation doubles.

Materials with high Verdet constants (positive or negative) result in a larger angle of rotation. The Verdet constant has positive values for diamagnetic materials and negative values for paramagnetic materials. Throughout the specification absolute values are used. Examples of materials with high Verdet constants are Barium hexaferrites, terbium gallium garnet and bismuth doped rare earth iron garnet. For example, terbium gallium garnet (TGG) has a Verdet constant of approximately-134 rad/(T·m) for 632 nm electromagnetic radiation. CeAlO3 270 rad/(T·m) at 632 nm, NaCe(MoO₄)2 204 rad/(T·m) at 632 nm. In a ferromagnetic or ferrimagnetic material, which has an internal magnetization, the total Faraday rotation angle for an optical wave traveling over a distance I through such a material is given by

$${θ}_{F} = \frac{{M}_{0 Z}}{{M}_{s}} l {P}_{F} \qquad Equation . 2$$

M_{0z} is the existing magnetization in the material and Mₛ is the saturation magnetization of the material.

The Faraday rotation depends on the surrounding magnetic field that is in turn magnetizing the magneto-optical layer. Rotation is maximized when the material is magnetized to reach its saturation magnetization.

Absolute value of faraday specific rotations PF for yttrium iron garnet 216°/cm and Yb_{y}BiₓY₃₋ₓ₋yFe₅O₁₂ 404°/cm (x=1.03, y=1.12), bismuth yttrium iron garnet 1250°/cm and Cerium yttrium iron garnet 1310°/cm at 1550 nm. (Bi, Y, Gd, Tm, Lu, Ca)3(Fe, Si)5O12 6500°/cm at 725 nm. (YYbBi)3Fe5O12 5000°/cm at 800 nm. Bismuth yttrium iron garnet 20,000°/cm at 590 nm. Bismuth yttrium iron garnet has one of the lowest absorption coefficient 2.7 dB cm⁻¹ at 1550 nm.

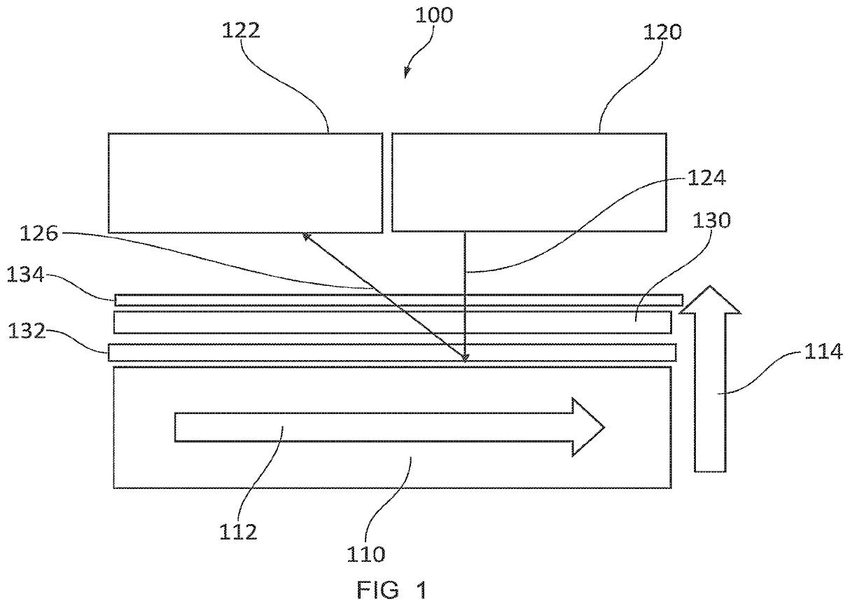

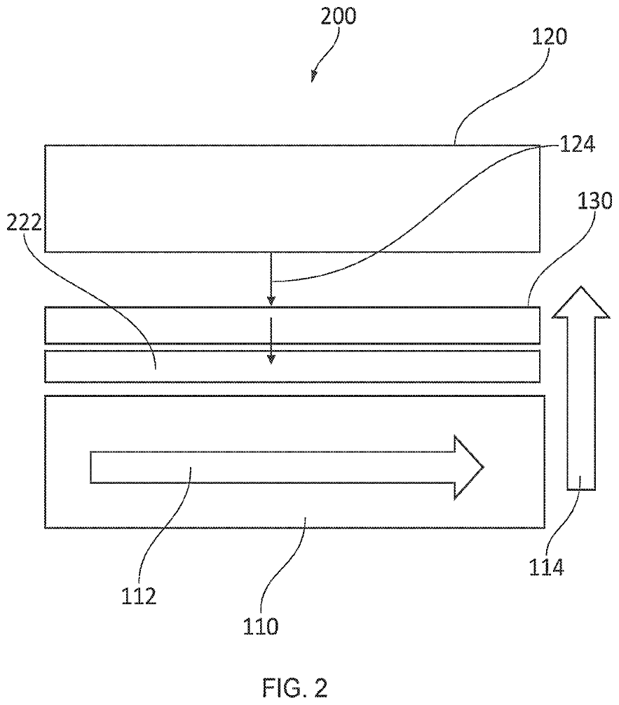

FIG. 1 and FIG. 2 illustrates schematic examples of systems 100, 200 for using the Faraday effect to monitor the current distribution of an electrochemical device. The direction of the electric current is shown by arrow 112 and the corresponding direction of the magnetic field is shown by arrow 114. The system includes an electromagnetic radiation source 120, a sensor 122, 222 and a magneto-optical medium 130.

The electromagnetic radiation source 120 is configured to direct polarized electromagnetic radiation 124 through the magneto-optical medium 130. In other words, the electromagnetic radiation source 120 emits electromagnetic radiation 124, which has been polarized, towards the magneto-optical medium 130. In the example shown by FIG. 1, the electromagnetic radiation passes through the magneto-optical medium 130 and is reflected, back through the magneto-optical medium to the sensor 122. The system 100 may therefore include a reflective layer 132, in some examples the electrochemical device 110 may be reflective or the reflective layer 132 and electrochemical device 110 may be integral. The reflective layer 132 may be formed of any reflective material, for example aluminium.

The electromagnetic radiation 124 may be emitted from the electromagnetic radiation source 120 in a direction which is parallel to the direction of the magnetic field 114 generated by the electrochemical device 110. The electromagnetic radiation 124 may be polarized when generated. In some examples the electromagnetic radiation source 120 may include polarization filters (not shown) so as to polarize the electromagnetic radiation 124. The electromagnetic radiation 124 may be linearly polarized.

The polarized electromagnetic radiation 124 travels through the magneto-optical medium 130 and the plane of polarization is rotated due to the Faraday effect as discussed above. Localised variations in the current flow 112 of the electrochemical device 110 results in a proportional change in the magnetic field 114. These changes in the magnetic field thus effect the angle of rotation of the plane of polarization of the electromagnetic radiation travelling through the magneto-optical medium 130.

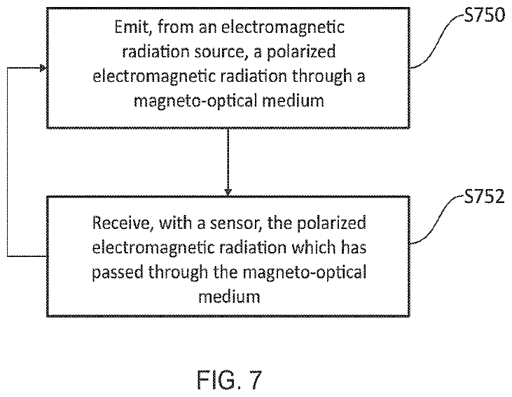

In the example system 100 shown in FIG. 1 the electromagnetic radiation 124 is reflected to the sensor 122. That is, the sensor 122 receives reflected, electromagnetic radiation which has passed through the magneto-optical medium 130, so the plane of polarization has been rotated. The sensor 122 or a control system (not shown) can then determine characteristics of the electrochemical device based on the received electromagnetic radiation 126 which has passed through the magneto-optical medium 130. This will be described in more detail below in reference to the methods of FIGS. 7 to 9.

The system 100 may include a reflective layer 132. In some examples, the magneto-optical medium 130 may include the reflective layer 132, a reflective surface may be otherwise applied to the electrochemical device 110. In some examples, the electrochemical device 110 may be reflective without the need for a reflective layer 132.

FIG. 2 shows an example system 200 with an alternative layout to that of FIG. 1. In this example, the system 200 has a sensor 222 positioned between the magneto-optical medium 130 and the electrochemical device 110. In this example electromagnetic radiation 124 travels through the magneto-optical medium to the sensor 222. That is, in the system shown by FIG. 2, the electromagnetic radiation 124 is not reflected.

In the systems 100, 200 of FIGS. 1 and 2 the magneto-optical medium 130 is positioned such that the magnetic field 114 of the electrochemical device 110 can interact with the magneto-optical medium 130, to rotate the polarization plane of the polarized electromagnetic radiation 124. For example, the distance between the magneto optical medium and the electrochemical device 110 may be 0.1 μm to 1000 μm. Aptly the distance may be 1 μm to 750 μm and more aptly 5 μm to 500 μm.

In some examples, the magneto-optical medium 130 may be coupled to the electrochemical device 110. For example, the magneto-optical medium 130 can be a layer adhered to a surface of the electrochemical device 110 or the reflective layer 132. In other examples the magneto-optical medium 130 may be integral with the electrochemical device. In this example the polarized electromagnetic radiation 124 passes through a portion of the electrochemical device 110 acting as the magneto-optical medium 130, before being received at the sensor 122.

The electromagnetic radiation source 120 may be any device capable of emitting polarized electromagnetic radiation. In some examples the electromagnetic radiation source 120 may be fibre optic cables which carry electromagnetic radiation 124 from an external source. These fibre optic cables may, in some examples, include a polarization filter.

The sensor 122 may be any device capable of receiving polarized electromagnetic radiation and obtaining a characteristic of the magnetic field 114 therefrom. For example, the sensor 122 may be a camera device. In other examples the sensor 122 may be a transmitting device which captures data such as the polarized electromagnetic radiation 126 which has travelled through the magneto-optical medium 130 and transmits it on to a control device (not shown). For example, fibre optic cables.

The sensor 122 may be capable of determining characteristics of the electrochemical device 110, for example the sensor 122 may be able to perform the methods described below to determine the current distribution over the electrochemical device 100. To this end, the sensor 122 may include an integrated control device capable of obtaining magnetic field data, based on the received polarized electromagnetic radiation 126.

The magneto-optical medium 130 is a medium through which electromagnetic radiation is able to propagate. For example, the magneto-optical medium 130 may be a transparent material. In some examples, the magneto-optical medium 130 may be a layer which is coupled to an electrochemical device. In other examples, the magneto-optical medium 130 may be part of a core of a fibre optic cable. The magneto-optical medium 130 may be between 0.01 μm and 750 μm thick. Aptly the magneto-optical medium 130 maybe between 0.1 μm and 500 μm thick and more aptly 0.6 μm to 10 μm thick.

In some examples, the magneto-optical medium 130 may include thin film magneto-optical crystals. The magneto-optical crystals may be embedded within a transparent material such as a polymer or glass fibre. These thin film magneto-optical crystals may be crystals with a high Verdet constant. In examples where the magneto-optical medium 130 is a ferromagnetic or ferrimagnetic material, the magneto-optical medium 130 may have high specific rotation and low optical absorption coefficient or high figure of merit ratio of former over latter greater than 10. In some examples the magneto-optical crystals include at least one of barium hexaferrites, terbium gallium garnet and bismuth doped rare earth iron garnet. Further alternative materials are Na₂Ce(MoO₄)₂ or CeAlO₃. Iron Garnet materials may be used due to their increased sensitivity compared with other known materials.

In some examples the system 100, 200 may also include one or more protective layers 134, shown in FIG. 1. The protective layer 134 may be configured to cover the magneto-optical medium 130 in order to provide additional protection. The protective layer 134 may therefore be transparent to the electromagnetic radiation 124. In some examples, the protective layer 134 may have a low Verdet constant such that there is negligible rotation of the polarization plane of electromagnetic radiation 124 in the protective layer 134.

The protective layer 134 may be an insulating polymer; or glass film. In examples where the magneto-optical medium includes magneto-optical crystals, the magneto-optical crystals can be embedded within a polymer or glass fibre. In other words, the protective layer 134 may be integral with the magneto-optical medium 130.

The electromagnetic radiation source 120 may emit a radiation of a predetermined wavelength. The wavelength of the radiation may be determined according to the magneto-optical medium 130 used. Aptly, the electromagnetic radiation 124 may be in the visible spectrum. Examples of suitable wavelengths include, but are not limited to 400 nm to 800 nm, aptly 500 nm to 700 nm, more aptly 550 nm to 600 nm. For example an electromagnetic wavelength of 590 nm may be used.

Further, in some examples the electrochemical device 110 may be a battery comprising a plurality of cells. Each of the plurality of cells may have an associated electromagnetic radiation source 120 and magneto-optical medium 130. In this way the system 100, 200 may include a plurality of electromagnetic radiation sources 120, each associated with one of the plurality of cells and a plurality of magneto-optical mediums, each again associated with one of the plurality of cells. In these examples, a single sensor 122 may be capable of receiving electromagnetic radiation 124 which has passed through one of the plurality of magneto-optical mediums 130 from each of the electromagnetic radiation sources 120. Alternatively, each of the plurality of cells may have an associated sensor 122. The system 100, 200 may operate the plurality of electromagnetic radiation sources 120 in series, such that each cell is monitored individually to build a picture of the current distribution across the battery. Similarly, the system 100, 200 may include a plurality of cells with associated sensors 122 and magneto-optical mediums 130 and a single electromagnetic radiation source. These arrangements allow mapping of different cells over very short periods of time.

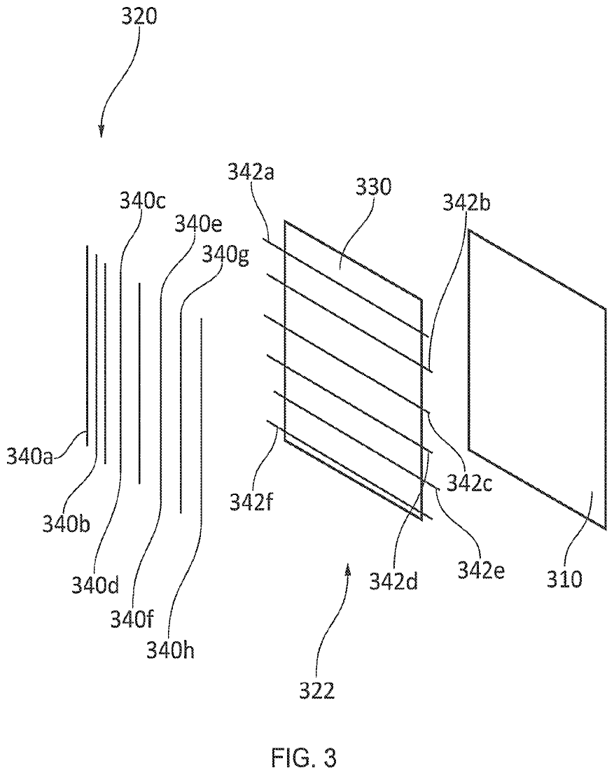

In some examples, one or both of an electromagnetic radiation source 320 or a sensor 322 may be a plurality of fibre optic cables 340, 342. An example of an arrangement of a fibre optic cables 340, 342 is illustrated in FIG. 3. In this example the electromagnetic radiation source 320 is a first plurality of fibre optic cables 340 and the sensor 322 is a second plurality of fibre optic cables 342. For example, the first plurality of fibre optic cables 340 may be connected to an external electromagnetic radiation source and configured to carry polarized electromagnetic radiation to the system. Similarly, the second plurality of fibre optical cables 342 may be configured to carry the polarized electromagnetic radiation which has passed through a magneto-optical medium 330 to an external sensor.

The first and second plurality of fibre optic cables 340, 342 may be arranged in a meshed or woven array. The fibre optic cables 340, 342 can be positioned adjacent to a magneto-optical medium 330 and electrochemical device 310.

The fibre optic cables 340, 342 may be arranged such that the magneto-optical medium 330 is sandwiched between the electromagnetic radiation source 320 (first plurality of fibre optic cables 340) and the sensor 322 (second plurality of fibre optic cables 342). Alternatively, the electromagnetic radiation source 320 (first plurality of fibre optic cables 340) and the sensor 322 (second plurality of fibre optic cables 342) may be an interwoven mesh or woven array. In some examples, one or both of the first or second plurality of fibre optic cables 340, 342 can be embedded inside the electrochemical device 310.

The fibre optic cables 340, 342 may in some instances be partially, or fully coated with a reflective layer which to helps to minimise electromagnetic radiation loss to the surroundings ensuring most captured electromagnetic radiation travels back along the fibre to the exterior sensor.

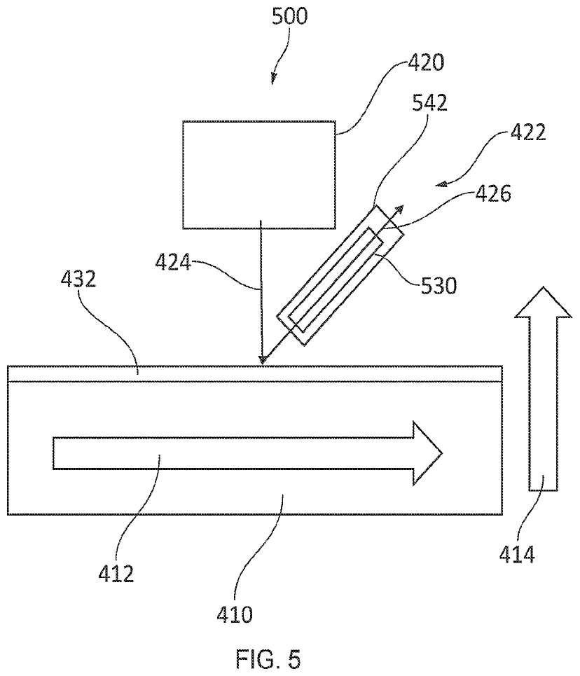

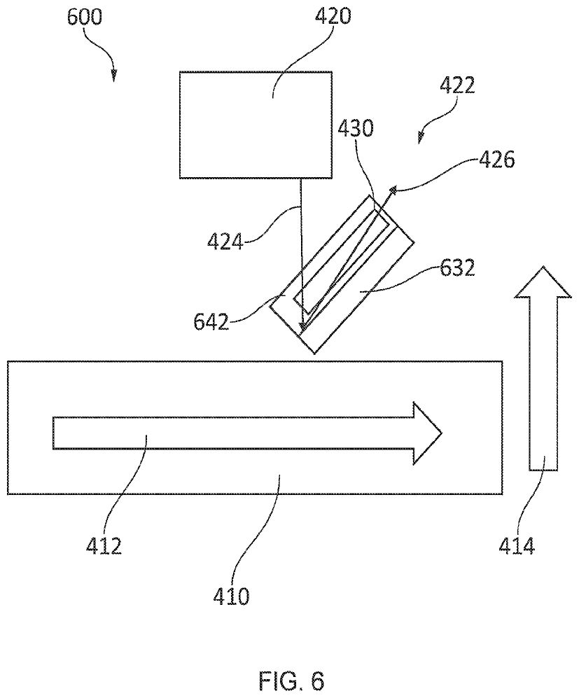

In a yet further example configuration, the magneto-optical medium 330 may include magneto-optical crystals. In this example the fibre optic cables 340, 342 and the magneto optical crystals can be embedded an electrochemical cell separator or solid electrolyte. The magneto-optical medium 330 may also be contained within the sensor 322 fibre optic cables (see FIGS. 5 and 6).

In examples where the electromagnetic radiation source 320 is a plurality of fibre optic cables 340, the magneto-optical medium 330 (and electrochemical device 310) may be illuminated in a sequential fashion. For example, the electromagnetic radiation source 320 may be a plurality of optical fibres 340a-h. The sensor 322 may be a plurality of optical fibres 342a-f arranged perpendicularly to the plurality of optical fibres 340a-h forming the electromagnetic radiation source 320. The fibre optic cables 340a-h, 342a-f cover the magneto-optical medium 330. The electromagnetic radiation source 320 may then emit electromagnetic radiation from a first fibre optic cable 340a then a second fibre optic cable 340b and so on. In this way a portion of the magneto-optical medium 330 is illuminated in a sequence across the overall surface. The sensor 322 may then receive the electromagnetic radiation and the current distribution over the electrochemical device may be mapped.

This sequential illumination may be any sequence, for example multiple cables may be emitting at once or just a single cable may be emitting. A controller (not shown) capable of controlling the sequences of emission may be included in the system.

In another example the magneto-optical medium 330 (and electrochemical device 310) may be illuminated by the fibre optic cables 340a-h where one or more of the fibre optic cables 340a-h are configured to emit a different wavelength of electromagnetic radiation. For example the electromagnetic radiation source 320 may emit electromagnetic radiation from a first fibre optic cable 340a at one wavelength and simultaneously emit electromagnetic radiation at a different wavelength from a second fibre optic cable 340b.

The different wavelengths can thus allow for improved positional mapping of current distributions.

In some examples, groups of fibre optic cables 340a-h may be illuminated sequentially, at different wavelengths. For example five adjacent fibre optic cables 340a-h may be illuminated simultaneously, each at a different wavelength, then unilluminated and the next five are then illuminated, again at different wavelengths and so on.

The plurality of fibre optic cables 340, 342 may have a diameter of 1 μm to 100 μm, aptly 3 μm to 75 μm and more aptly 5 μm to 50 μm. The plurality of fibre optic cables 340, 342 may be arranged such that 1 cm of magneto-optical medium may have from 1 to 10,000 fibre optic cables 340, 342 across its surface area aptly 1 cm of magneto-optical medium may have from 10 to 1000 fibre optic cables 340, 342 across its surface area. For example, if optical resolution of 10 μm is required then 1000 fibres with 10 μm diameter are arranged across 1 cm of the magneto-optical medium's surface area.

By using fibre optic cables for one or both of the electromagnetic radiation source 320 or sensor 322 it is possible to build a detailed map of the magnetic field and thus current distribution of the electrochemical device 310. Moreover, in examples where the system is built up of multiple electrochemical devices 310 such as battery cells or electrolyser stacks, the use of fibre optical cables allows for a monitoring system to be installed without substantial increase in the size of the overall device.

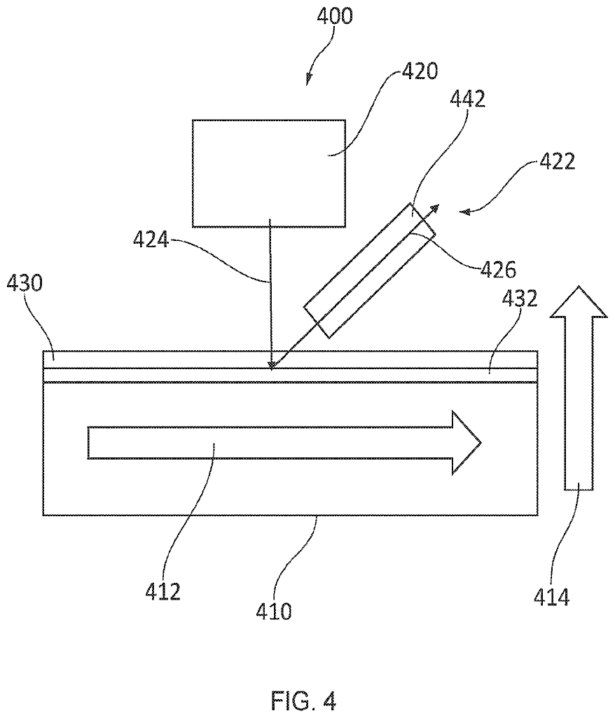

Referring now to FIGS. 4 to 6, example arrangements of a system 400, 500, 600 including fibre optic cables are illustrated schematically. These figures illustrate a single fibre optic cable 442, 542, 642 for clarity, and it should be understood that a plurality of fibre optic cables can be used for each embodiment illustrated.

In the example shown in FIG. 4 the system 400 includes an electromagnetic radiation source 420 which may be a electromagnetic radiation source or fibre optic cable array, as discussed above. The electromagnetic radiation source 420 is configured to emit polarized electromagnetic radiation 424 towards a magneto-optical medium 430. Where the magneto-optical medium 430 is adjacent an electrochemical device 410, which includes a current 412 flowing across the device 410 and thus generates a perpendicular magnetic field 414. In the example of FIG. 4 the magneto-optical medium 430 is coupled to the electrochemical device 410. A reflective layer 432 is sandwiched between the magneto-optical medium 430 and the electrochemical device 410. The reflective layer 432 reflects the polarized electromagnetic radiation 424 back through the magneto-optical medium 430, such that the polarized electromagnetic radiation 424 passes through the magneto-optical medium 430 twice. The reflected polarized electromagnetic radiation 426 is received by a sensor 422 which is a fibre optic cable 442.

In the example shown in FIG. 5 the system 500 includes a similar configuration to that of FIG. 4. However, in this example the sensor 422 is a fibre optic cable 542 which includes a magneto-optical medium 530. In this example, the electromagnetic radiation source 420 emits polarized electromagnetic radiation 424 to the reflective layer 432 coupled to the electrochemical device 410. The reflected polarized electromagnetic radiation 426 passes through the magneto-optical medium 530 in the fibre optic cable 542. That is, the polarized electromagnetic radiation 424 only passes through the magneto-optical medium 530 once (after reflection).

In the example shown in FIG. 6, the sensor 422 is a fibre optic cable 642 which includes a magneto-optical medium 630 as in FIG. 5. Additionally, the fibre optic cable 642 includes a reflective layer 632 which may partially cover the fibre optic cable 642. In this example, the electromagnetic radiation source 420 emits polarized electromagnetic radiation 424 to the reflective layer 432 partially covering the fibre optic cable 642.

The reflected polarized electromagnetic radiation 426 passes through the magneto-optical medium 630 in the fibre optic cable 642. In this way the fibre optic cable 642 need only be placed close to the electrochemical device 410. That is, the fibre optic cable 642 must be sufficiently close to the electrochemical device 410 such that the magneto-optical medium 630 can interact with the magnetic field 414 in order to rotate the polarization plane of the polarized electromagnetic radiation 424. The reflective layer 432 may be positioned atop the magneto-optical medium 630. In this way the electromagnetic radiation travel twice through the magneto-optical medium 630; once as incident beam and second time as a reflected beam.

The reflective layer 432 may be included on the fibre optic cable 642 by coating an exterior side of the fiber with reflective coating. This improves the efficiency of electromagnetic radiation traveling back to sensor 422 and reduces the amount of electromagnetic radiation radiating elsewhere. In other words a section of fibre optical cable 642 which faces the electrochemical device 410 doesn't have reflective coating while the section facing away from the electrochemical device 410 has a reflective layer 342.

Turning to FIG. 7, an example method of utilising the systems described above is illustrated. A first step S750 includes emitting, from an electromagnetic radiation source, a polarized electromagnetic radiation through a magneto-optical medium. The magneto-optical medium is positioned relative to an electrochemical device with a current passing through it, such that the magnetic field generated by the current flow interacts with the magneto-optical medium. The magneto-optical medium will cause the plane of polarization of the electromagnetic radiation to rotate due to the Faraday effect. This rotation is proportional to the magnetic field strength of the electrochemical device. A sensor then receives the polarized electromagnetic radiation which has passed through the magneto-optical medium (and so undergone rotation) in step S752. The amount of rotation of the polarized electromagnetic radiation will vary according to the variations in current distribution across the electrochemical device. This method can occur simultaneously at multiple positions across the electrochemical device; in some cases, the method may be repeated at multiple positions across the electrochemical device.

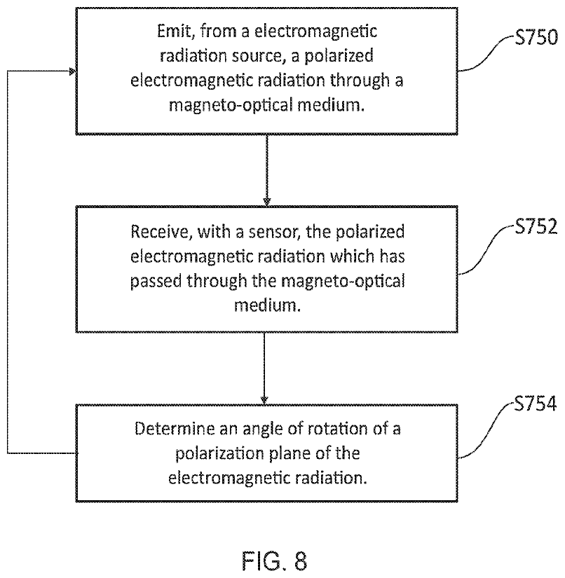

As shown in FIG. 8, the angle of rotation of a polarization plane of the electromagnetic radiation can then be determined in step S754. The angle of rotation of a polarization plane can be determined by comparison of the received electromagnetic radiation polarization plane compared with the known emitted polarization plane. The angle of rotation may also depend on the times the electromagnetic radiation passes through the magneto-optical medium. For example in systems which use reflection to the sensor, the magneto-optical medium may doubly rotate the polarization plane. The calculation of the angle of rotation will thus depend on the configuration of the system. The system may include a controller for performing these calculations in some examples.

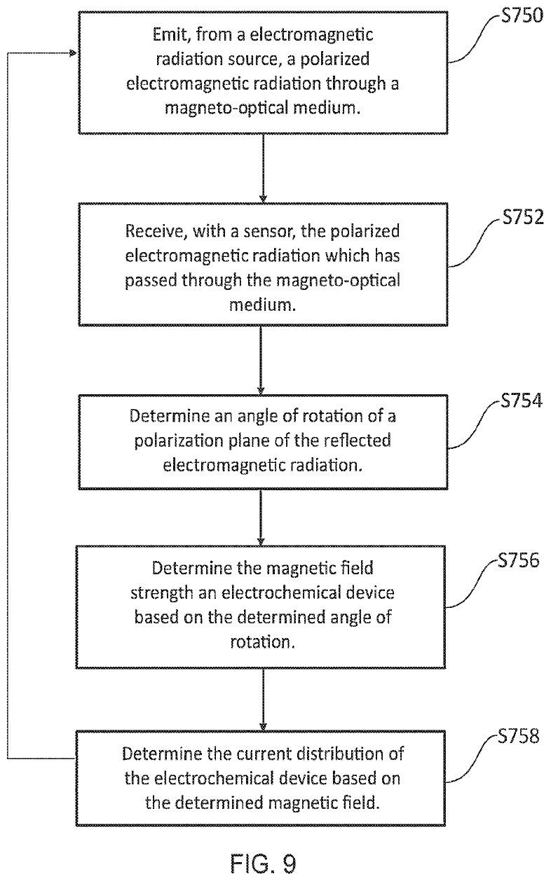

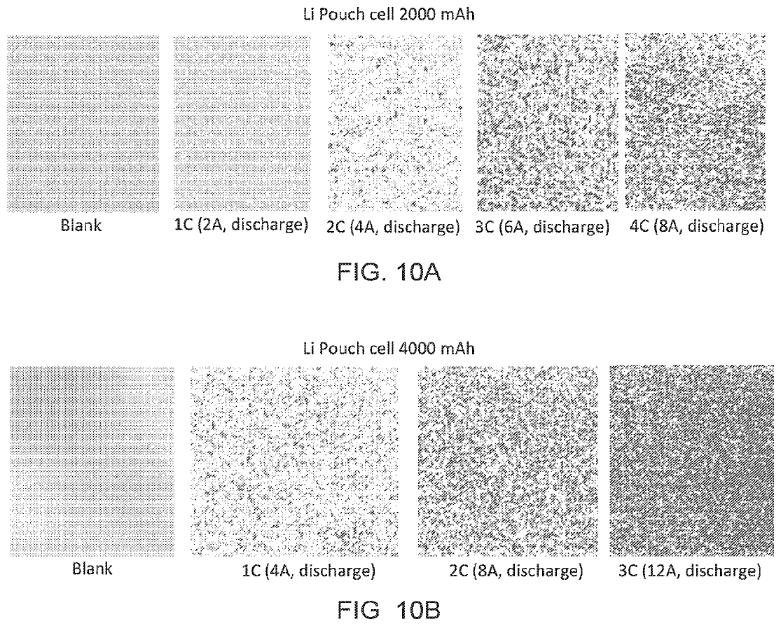

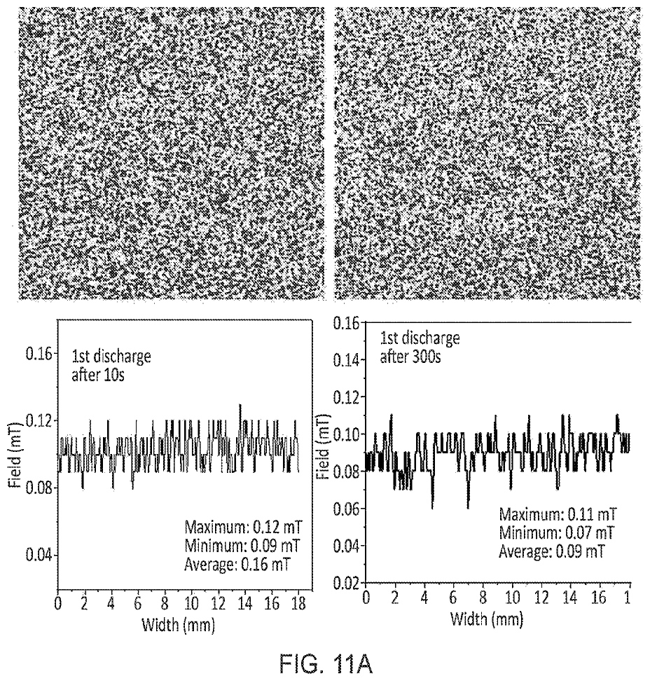

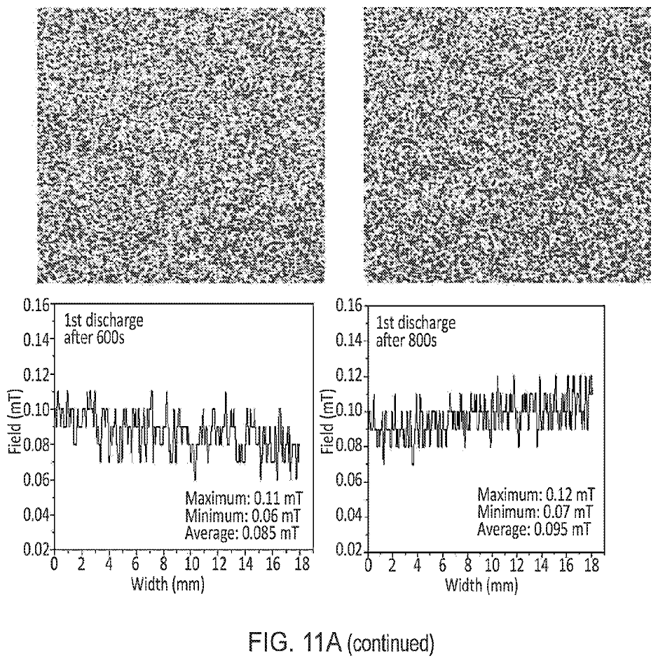

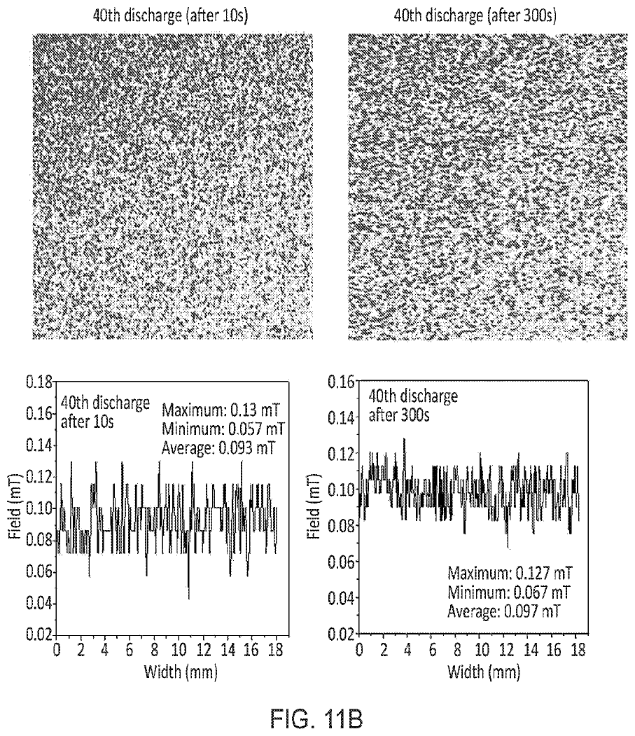

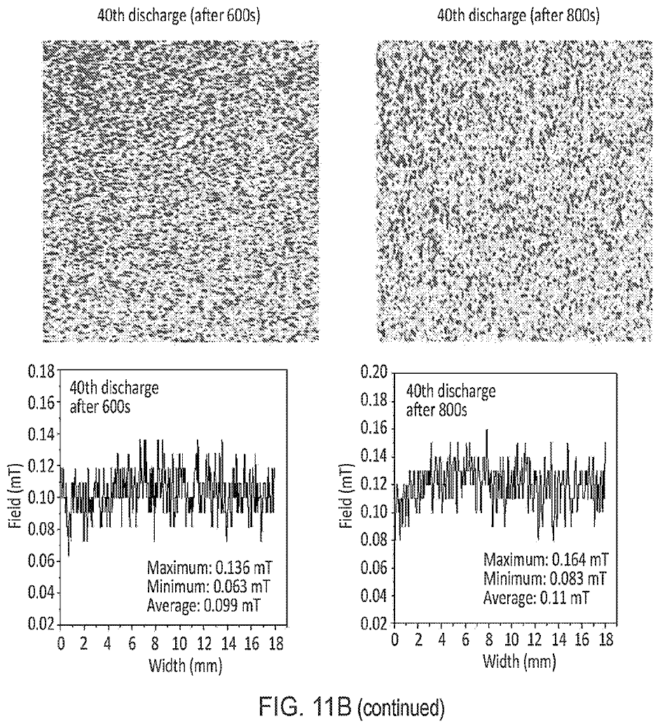

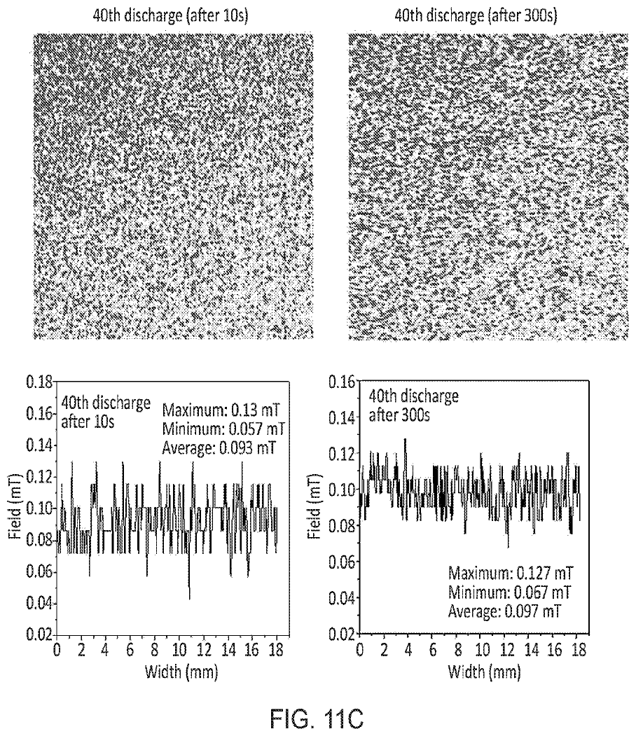

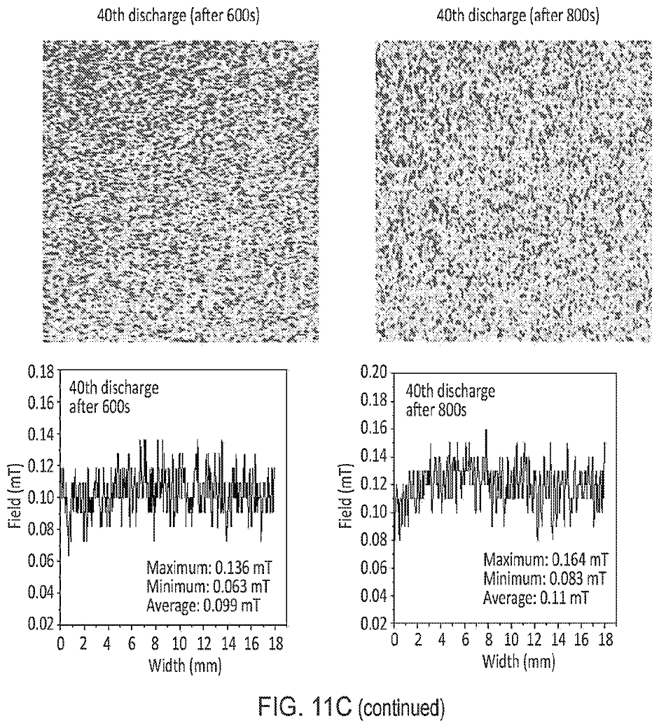

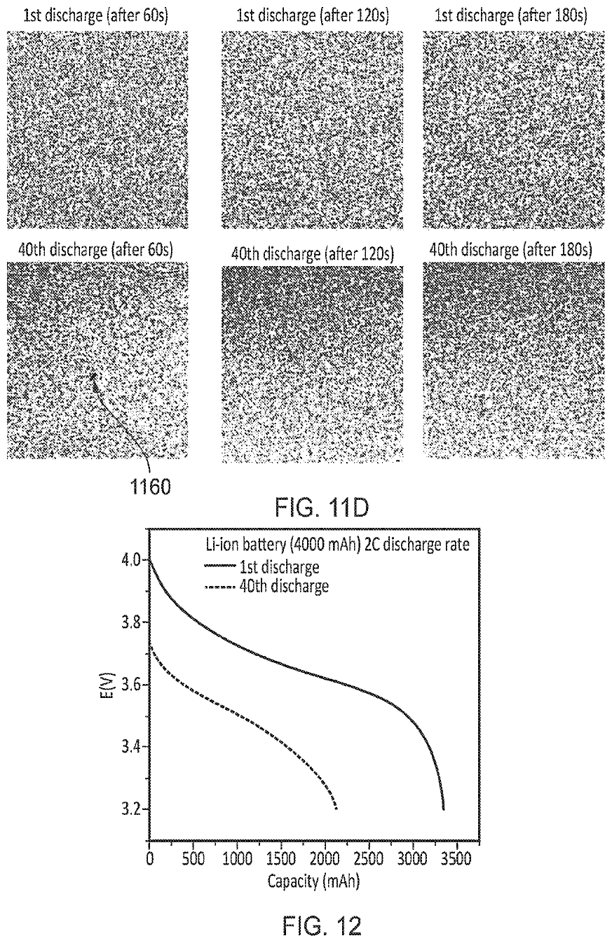

As shown in FIG. 9, the strength of the magnetic field can therefore be determined based on the angle of rotation of the polarization plane in step S756. The magnetic field may be determined using Becquerel's formula. The variation in magnetic field will therefore be illustrated by the different angels of rotation. This allows for a system with a sensitivity from 0 mT to 10 mT, aptly 0 mT to 5 mT and most aptly 0 mT to 2.5 mT. This magnetic field variations can be mapped positionally across the electrochemical device. This advantageously allows for the generation of a magnetic flux density map of the electrochemical device, as shown in FIGS. 10A to 11D.

In step S758, the corresponding local current in the mapped area can then be calculated based on the determined magnetic field strength. This can then be converted into a current density distribution map. The conversion can either done by scaling the magnetic flux density map with the ratio of discharge (or charge current) over average recorded magnetic field flux of the whole battery. In the examples of FIGS. 11B and 11C this would be by a factor of 40 (4A/0.1 mT). The average flux density in this example may be obtained from analysis (using conventional methods) of small section of battery and not the whole battery.

Alternatively, more accurate conversion can be done by converting the magnetic flux density to magnetic field strength using a materials permeability in the order of 10⁻⁶ H/m for air/Aluminium. Flux density of 0.1 mT will translate to 100 A/m. By knowing the distance of battery electrode from the magneto-optical layer of the sensor e.g. 220 μm an equivalent electrical current of 22 mA can be said to be passing in the electrode current collector in the mapped area were the magnetic flux density was detected. By dividing the current by the area where it was detected, current density can be obtained.

These current-distribution maps can be produced over time, for example FIGS. 11A and 11B each illustrates four current distribution maps at different time periods, where FIG. 11A shows an electrochemical device on a first discharge and FIG. 11B shows the electrochemical device on a 40^{th} discharge. As can be seen from these figures, current distribution map changes as a battery is aged and cycled. This shows a direct correlation between heterogeneity in current density and electrochemical device by age by comparing data at top of 1st cycle and at bottom after 40 cycles. This allows for the identification of current hot spots 1160, such as that shown in FIG. 11D. A hot spot 1160 may be considered an areas with very high localised magnetic flux compared to the surrounding, for example greater than 30% of the average value. Formation of hot spots and dendrite formation are indicative of a risk of thermal runaway, in particular if they are persistently detected in same area over prolonged periods. They could also indicate of fault in battery manufacturing and can be used for quality control assessment.

This variation in current density can therefore be monitored to assess quality control of device fabrication, detection of aging, estimate lifetime, prediction of failure mode or produce corrective action via system control. For example, this method can detect flooding in fuel cell or aging in batteries where direct correlation is seen between variation in local current density and batteries aging. In addition, the method can highlight and area of very high or low current density, which may correlate with imminent failure. The information can be fed back to control system to take mitigation action for example in battery lower charge or discharge rate or tigger alarm for service. It could also be used to locate the faulty cell from large pack of cells and locate also the area within a cell itself or for quality control assessment of batteries after manufacturing.

### Examples

Two Li-ion pouch and prismatic cells were tested. Cells with capacity of 2000 and 4000 mAh were tested. The 2000 mAh had an outside dimensions of 40×55×5.8 mm (Height, Width, Thickness) with total electrode area of 440 cm² (80×5.5 cm, wrapped). Magnetic flux density maps could be detected from 2 C (4 A) as can be seen in FIG. 10A. This translates to current density of 4/440=90 mA cm⁻². Similarly, for 4000 mAh battery FIG. 10B, magnetic field mapping was visible from current of 4 A and above i.e. rate of discharge of 1 C or current density equal to 4/870=46 mA cm⁻². The cell had dimensions of 50 by 100 by 5 mm (Height, Width, Thickness) with total electrode area of 870 cm² (87 by 100 cm, wrapped).

The outside insulation of prismatic cells had a thickness of 220 μm. An anode active layer of graphene with total thickness of 70 μm split on either side of 50 μm Copper foil. Cathode active layer of Nickel-manganese-cobalt oxide layer with total thickness of 45 μm was coated on either side of 25 μm Aluminium foil. Batteries were charged and discharged at rates 1-4 C.

A section of the 4000 mAh battery was placed flat onto a 20.5 mm by 15.5 mm sensor consisting of glass substrate coated with thin magneto-optical coating (1 to 10 μm of bismuth-substituted rare-earth-iron-garnet single crystal film layer with faraday specific rotations PF>1°/μm (or 10,000°/cm at 590 nm) topped with 5 μm of reflective aluminium layer with protective polymer surface. Substituted iron garnet films have the highest magnetic resolution among all magneto-optical materials employed as visualizers, magnetic fields down to 10 A/m or magnetic field flux of 0.01 mT can be detected [M. R. Koblischka and R. J. Wijngaarden. Magneto-optical investigations of superconductors. Supercond. Sci. Technol., 8:199, 1995.]. The sensor saturation range was around magnetic flux density of 2 mT or magnetic field strength of 2 kA/m considering permeability in the order of 10⁻⁶ H/m (for air, copper or Aluminium) with working range of 0.05 to 2.0 mT.

The resulting Faraday rotation when using polarised light with 590 nm wavelength equal to 1.5°/mT per single pass or 3°/mT for double passed reflected light at room temperature through the sensor (effectively double distance travel or layer thickness). For magnetic flux density of lower detection limit of the used sensor of 0.05 mT, a rotation in polarised light by 0.15° will be detected. A polarised light with wavelength equal to 590 nm was emitted on the back surface of the glass substrate i.e. the opposite surface to were battery was placed. The light passes the glass and magneto optical layer and then is reflected back by the aluminium mirror layer double passing the magneto optical layer and through the glass with different rotation angles depending on the local magnetic flux density. The reflected light then passes via analyser-polarization filter module, and then to a 5 MP CCD camera to create an intensity-contrast image which represents a map of the magnetic field distribution of the battery with optical resolution of resolution 25 μm. Evolution of magnetic flux density map with time and charge/discharge cycles (1 and 40) can be seen in FIGS. 11B and 11C. It can be seen that despite the modest current density and charging rate of 2 C good detection of magnetic flux density map could be obtained reflecting significant variation in current distribution in the battery electrodes.

For electric vehicles much high charge rates of 4-10 C is desired through rapid charging. Analysis of the map can identify regions with poor magnetic flux density over time (below 20% of average) and those with high magnetic flux density over time (above 20% of average). It also shows for a given cycle the heterogeneity of discharge or charge in electrode i.e. how over time during the cycle most active areas start discharging (or charging) first moving towards less active areas with time as battery voltage decrease (or increase). Small areas with very high localised magnetic flux (>50% of average value) could indicated formation of hot spots and dendrite formation with risk of thermal runaway if they persistently detected in same area over prolonged periods. For example, in FIG. 11D an area of hot spot 1160 is detected at 60s (40th discharge). This high activity was not detected previously at 10 s of discharge (FIG. 11C) or afterwards 120s (FIG. 11D) and therefore is not considered as risk of forming dendrite which is expected here given the battery is at beginning of discharge state.

On the other hand, prolonged detection of hot spots over 100s of seconds towards end of charge cycles could be series indicators of dendrites formation or imminent serious battery failure. Various analysis could be done on the captured map/data for example minimum/maximum and average of magnetic flux density in the map. This can be done by selecting a specific area or line in X or Y axis. An example of simple analysis by selecting a line in the middle of y-axis showing variation of magnetic flux density along the x-axis is shown. The increase in standard deviation of magnetic field flux density with battery aging is evident from simple analysis shown in FIGS. 11C and 11D. More complex analysis of the whole mapped area will be more useful. For example, it is clear from FIGS. 11B to 11D that with aging the magnetic field distribution throughout the electrode become less uniform and become more denser towards the top and top left of the monitored area of the electrode. The significant loss of capacity by from 3400 to 2200 mAh at discharge rate of 8A between 1st and 40th cycle can be clearly seen in FIG. 12.

Although multiple system arrangements have been described in the specification, it is envisaged that any arrangement which capable of utilising the faraday effect to measure current distribution of an electrochemical device falls within the scope of the claims. In addition, features only described in relation to a single example may be included in other examples, unless otherwise specified.

Although illustrated throughout the figures as having current flowing left to right resulting in an upward direction magnetic field (when viewed on the page) it should be understood that the current direction can be any direction and the resulting magnetic field can thus be any perpendicular direction.

The sensors described above may be retro-actively attached to electrochemical devices or provided separately to be used with an electrochemical device.

The above-described system, sensors, and methods advantageously provided an improved way of monitoring an electrochemical device, which is non-invasive to the electrochemical device. Further, the above-described system, sensors, and methods can detect variations in the electrochemical device, thus the non-homogenous nature of an electrochemical device does not mask issues which may otherwise remain undetected.

Throughout this specification, the words “comprise” and “contain” and variations of them mean “including but not limited to”, and they are not intended to (and do not) exclude other components, integers or steps. Throughout this specification, the singular encompasses the plural unless the context otherwise requires. In particular, where the indefinite article is used, the specification is to be understood as contemplating plurality as well as singularity, unless the context requires otherwise. Throughout this specification, the term “about” is used to provide flexibility to a range endpoint by providing that a given value may be “a little above” or “a little below” the endpoint. The degree of flexibility of this term can be dictated by the particular variable and can be determined based on experience and the associated description herein.

Features, integers or characteristics described in conjunction with a particular aspect or example of the invention are to be understood to be applicable to any other aspect or example described herein unless incompatible therewith. All of the features disclosed in this specification, and/or all of the steps of any method or process so disclosed, may be combined in any combination, except combinations where at least some of such features and/or steps are mutually exclusive. The invention is not restricted to the details of any foregoing examples. The invention extends to any novel feature or combination of features disclosed in this specification. It will be also be appreciated that, throughout this specification, language in the general form of “X for Y” (where Y is some action, activity or step and X is some means for carrying out that action, activity or step) encompasses means X adapted or arranged specifically, but not exclusively, to do Y.

Each feature disclosed in this specification may be replaced by alternative features serving the same, equivalent or similar purpose, unless expressly stated otherwise. Thus, unless expressly stated otherwise, each feature disclosed is one example only of a generic series of equivalent or similar features.

The reader's attention is directed to all papers and documents which are filed concurrently with or previous to this specification in connection with this application and which are open to public inspection with this specification, and the contents of all such papers and documents are incorporated herein by reference.

1. A system comprising:
an electrochemical device generating a magnetic field; and
a sensing device comprising:
a magneto-optical medium;
an electromagnetic radiation source configured to emit polarized electromagnetic radiation through the magneto-optical medium; and
a sensor configured to receive polarized electromagnetic radiation which has passed through the magneto-optical medium;
wherein the sensing device is arranged relative to the electrochemical device such that the magnetic field of the electrochemical device passes through the magneto-optical medium.

2. The system as claimed in claim 1, where the magneto-optical medium is positioned such that the magnetic field of the electrochemical device interacts with the magneto-optical medium to rotate a polarization plane of the polarized electromagnetic radiation based on a characteristic of the electrochemical device.

3. The system as claimed in claim 1 or 2, wherein the electromagnetic radiation source is arranged relative to the electrochemical device such that the emitted polarized electromagnetic radiation is parallel to the generated magnetic field of the electrochemical device.

4. The system as claimed in any preceding claim, wherein the magneto-optical medium is integral with the electromagnetic radiation source; or
wherein the magneto-optical medium is a layer coupled to the electrochemical device.

5. The system as claimed in any preceding claim, wherein the magneto-optical medium comprises thin film magneto-optical crystals.

6. The system as claimed in claim 5, wherein the sensing device further comprises a protective layer of an insulating polymer or glass film for protecting the thin film magneto-optical crystals; or wherein the magneto-optical crystals are embedded with a polymer or glass fibre for protecting the thin film magneto-optical crystals.

7. The system as claimed in any proceeding claim, wherein the magneto-optical crystals have a high Verdet constant or low optical adsorption; or
wherein the magneto-optical crystals comprise at least one of barium hexaferrites, terbium gallium garnet, bismuth doped rare earth iron garnet, Na₂Ce(MoO₄)₂ or CeAlO₃.

8. The system as claimed in any preceding claim, wherein the electrochemical device generating a magnetic field is a battery comprising a plurality of cells;
wherein the system comprises a plurality of electromagnetic radiation sources, each associated with one of the plurality of cells; and
wherein the system further comprises a plurality of magneto-optical mediums, each associated with one of the plurality of cells.

9. The system as claimed in claim 8, wherein the system is configured to operate the plurality of electromagnetic radiation sources in series; and
wherein the sensor is configured to receive polarized electromagnetic radiation which has passed through one of the plurality of magneto-optical mediums from each of the electromagnetic radiation sources.

10. The system as claimed in claim 8, wherein the system further comprises a plurality of sensors associated with the plurality of electromagnetic radiation sources.

11. The system as claimed in any preceding claim, wherein the system comprises a control module configured to:
determine a first polarization plane of the emitted electromagnetic radiation, or store a predetermined polarization plane of the emitted electromagnetic radiation;
determine a second polarization plane of the electromagnetic radiation which has passed through the magneto-optical medium;
determine an angle of rotation between the first and second polarization planes;
determine a magnetic field strength of the electrochemical device based on the determined angle of rotation; and
determine the current distribution of the electrochemical device based on the determined magnetic field.

12. A method of sensing comprising:
providing the system of any preceding claim;
emitting, from the electromagnetic radiation source, a polarized electromagnetic radiation through the magneto-optical medium;
receiving, with the sensor, the polarized electromagnetic radiation which has passed through the magneto-optical medium.

13. The method as claimed in claim 12, wherein the method further comprises:
determining an angle of rotation of a polarization plane of the reflected electromagnetic radiation.

14. The method as claimed in claim 13, wherein the method further comprises:
determining the magnetic field strength an electrochemical device based on the determined angle of rotation; and
determining the current distribution of the electrochemical device based on the determined magnetic field.

15. The method as claimed in claim 14, further comprising repeating the determination of the current distribution of the electrochemical device periodically or for a plurality of positions upon the electrochemical device; and determining a temporal or spatial variation in current distribution information of the electrochemical device.

16. The method as claimed in claim 15, wherein emitting the polarized electromagnetic radiation to a magneto-optical medium comprises emitting the electromagnetic radiation from a plurality of fibre optic cables.

17. The method as claimed in claim 16, wherein the electromagnetic radiation is emitted from the plurality of fibre optic cables independently over the time period such that the electromagnetic radiation is incident on the magneto-optical medium in a pattern or series.

18. The method as claimed in claim 16 wherein the electromagnetic radiation is emitted from the plurality of fibre optic cables simultaneously and the plurality of fibre optic cables are configured to emit a different wavelength of electromagnetic radiation to an adjacent fibre optic cable.

19. The method as claimed in any one of claim 15 to claim 18, wherein the system comprises a control module configured to receive the variation in current distribution information; and
wherein the control module is configured to change a parameter of the electrochemical device based on the variation in current distribution information; or
wherein the control module is configured to trigger an alarm based on the variation in current distribution information.

20. A sensing device comprising:
a magneto-optical medium;
an electromagnetic radiation source configured to emit polarized electromagnetic radiation through the magneto-optical medium; and
a sensor configured to receive polarized electromagnetic radiation reflected from the electromagnetic radiation source through the magneto-optical medium,
wherein the electromagnetic radiation source comprises a first plurality of fibre optic cables, or wherein the sensor comprises a second plurality of fibre optic cables.

21. A sensing device as claimed in claim 18, further comprising at least one of a reflective layer or a protective medium.

22. The sensing device of claim 18, wherein the first plurality of fibre optic cables and the second plurality of fibre optic cables are arranged in a mesh or woven array.

23. The sensing device of claim 20, wherein at least one of the first or second plurality of fibre optic cables is configured to be embedded inside the electrochemical device.

24. The sensing device of any one of claims 20 to 21, wherein the first plurality of fibre optic cables are configured to emit electromagnetic radiation independently over a period of time such that the electromagnetic radiation is incident on the magneto-optical medium in a pattern or series; or
wherein the electromagnetic radiation is emitted from the first plurality of fibre optic cables simultaneously and the first plurality of fibre optic cables are configured to emit a different wavelength of electromagnetic radiation to an adjacent fibre optic cable.

25. A sensing device comprising:
an electromagnetic radiation source comprising a first plurality of fibre optic cables for emitting polarized electromagnetic radiation; and
a sensor configured to receive polarized electromagnetic radiation, wherein the sensor comprises the magneto-optical medium such that the polarized electromagnetic radiation from the electromagnetic radiation source passes through magneto-optical medium.

26. The sensing device of claim 23, wherein the sensor comprises a second plurality of fibre optic cables; and
wherein the second plurality of fibre optic cables contain the magneto-optical medium.

27. The sensing device of claim 24, wherein the at least one fibre optic cable comprises a reflective layer.

28. The sensing device of any of claims 23 to 25, wherein the first plurality of fibre optic cables and the second plurality of fibre optic cables are arranged in a mesh or woven array.

29. The sensing device of claim 26, wherein at least one of the first or second plurality of fibre optic cables are configured to be embedded inside the electrochemical device.

30. The sensing device of any of claims 25 to 29, wherein the first plurality of fibre optic cables are configured to emit electromagnetic radiation independently over a period of time; or
wherein the electromagnetic radiation is emitted from the first plurality of fibre optic cables simultaneously and the first plurality of fibre optic cables are configured to emit a different wavelength of electromagnetic radiation to an adjacent fibre optic cable.

31. Use of a sensing device according to any one of claims 18 to 30 for determining current variation in an electrochemical device.
